(19) United States
(12) Patent Application Publication
(10) Pub. No.: US 2010/0300510 A1
(43) Pub. Date: Dec. 2, 2010

(54) SOLAR ENERGY SYSTEMS WITH REFLECTING AND PHOTOVOLTAIC CONVERSION MEANS

(75) Inventors: Arnold J. Goldman, Jerusalem (IL); Binyamin Koretz, Eilat (IL); Yoel Gilon, Jerusalem (IL)

Correspondence Address: MILES & STOCKBRIDGE PC, 1751 PINNACLE DRIVE, SUITE 500, MCLEAN, VA, 22102-3833, US

(73) Assignee: BrightSource Industries (ISRAEL), Ltd.

(21) Appl. No.: 12/669,963

(22) PCT Filed: Jul. 23, 2008
(86) PCT No.: PCT/US08/70910

§ 371 Date: May 7, 2010

Related U.S. Application Data
(60) Provisional application No. 61/053,035, filed on May 14, 2008.
(60) Provisional application No. 60/951,241, filed on Jul. 23, 2007.

(51) Int. Cl. H01L 31/052

(52) U.S. Cl. 136/246

(57) ABSTRACT

A solar power system may include at least one reflector The reflector may have a surface configured to convert a first part of the sunlight incident thereon to electrical power The surface of the reflector may also be configured to reflect a second part of the sunlight incident thereon The at least one reflector may be configured to direct the second part of the sunlight incident thereon to a solar receiver A power management system may also be provided The power management system may receiver electrical power derived from the first part from the reflector.

### CROSS REFERENCE TO RELATED APPLICATIONS

This application claims priority to U.S. Provisional Patent Application No. 60/951,241, filed on 23 Jul. 2007, and U.S. Provisional Patent Application No. 61/053,035, filed on 14 May 2008.

### FIELD OF THE INVENTION

This invention relates generally to the conversion of solar radiation to electric power, and more particularly to a solar power system with reflecting and conversion means.

### SUMMARY OF THE INVENTION

The invention provides an efficient system for the conversion of solar radiation to thermal and electric energy, as well as components, articles of manufacture, and other technological improvements, and methods for using them.

In an embodiment of the present invention, an apparatus for use in a solar concentrating system may include (i.e., comprise) a receiving member having (i.e., comprising) layers configured respectively for reflecting and converting solar energy received thereby. The layers may be in a mutually overlying arrangement and configured such that a first part of the solar received thereby is converted to energy of another form and a second part is reflected to a solar energy receiver. The apparatus may also include at least one energy power output configured to convey converted solar energy from the receiving member.

In another aspect, the apparatus may also include a drive system configured to aim the receiving member. The drive system may be configured to receive energy from the energy power output.

In another aspect, the layers of the apparatus may include a photovoltaic conversion layer. The energy of another form may be electrical energy.

In another aspect, the apparatus may also include a drive system configured to aim the receiving member such that solar energy is received normal to the layers at a first time and to selectively aim the receiving member such that the second part is reflected to a solar energy receiver at second time.

In another aspect, the layers may include a photovoltaic converting layer and a reflecting layer. In yet another aspect, the layers may include a photovoltaic that is at least partly transparent and a reflecting layer. In yet another aspect, the layers may include a waveband filter layer, a photovoltaic converting layer, and a reflecting layer. In still another aspect, the layers may include a dichroic filter layer, a photovoltaic converting layer, and a reflecting layer. In another aspect, the layers may include a photovoltaic converting layer and a reflecting layer with variable reflectivity. In another aspect, the layers may include a photovoltaic layer and at least one of a reflecting layer and a dichroic filter layer. In still another aspect, the layers may include a filter layer and a photovoltaic layer having a range of wavelengths over which the photovoltaic layer exhibits peak conversion efficiency, the filter layer being configured to reflect light of wavelengths outside said range of wavelengths and to transmit light of wavelengths within said range of wavelengths.

In another aspect, the receiving member may have a dish-shaped configuration to concentrate the solar energy onto a solar energy receiver.

Another embodiment of the present invention may include a method for controlling at least one heliostat in a solar power system. The at least one heliostat may have a reflecting layer and a conversion layer arranged such that light is incident on both layers simultaneously. Alternately, the at least one heliostat may have a reflecting layer and a conversion layer arranged such that a light ray is capable of passing through both layers. The reflecting layer may reflect a portion of incident solar radiation. The conversion layer may generate electrical power from another portion of the incident solar radiation. The method may include aiming the at least one heliostat so as to reflect incident solar radiation onto to a solar receiver at a first time. The method may further include aiming the at least one heliostat toward a different direction responsively to at least one of an excess flux condition, a low direct insolation condition, a non-steady state operating condition of a boiler, and a condition of non-uniform illumination of the conversion layer at a second time.

In another aspect, the aiming the at least one first heliostat toward a different direction may result in a greater conversion efficiency for the conversion layer.

In another aspect, the second time may include a time when insolation levels are below a predetermined threshold for use by the solar receiver.

In yet another aspect, the second time may include a time when the at least one heliostat contributes more to electricity production by aiming the at least one heliostat directly at the sun than by reflecting incident solar radiation to the solar receiver.

Another embodiment of the present invention may include a solar power system. The solar power system may include at least one reflector having a surface configured to convert a first part of the sunlight incident on the surface to electrical power and to reflect a second part of the sunlight incident on the same surface. The at least one reflector may be configured to direct the second part of the sunlight incident thereon to a solar receiver. The solar power system may further include a power management system configured to receive electrical power derived from the first part from the reflector.

In another aspect, the solar receiver may include a photovoltaic converter. In yet another aspect, the reflector may include co-planar reflecting and photovoltaic conversion layers.

In another aspect, the at least one reflector may include multiple reflectors and the solar receiver may include a solar thermal boiler. In another aspect, the reflector may be a heliostat. In a further aspect, the solar power system may include multiple heliostats. The reflector may receive sunlight from the multiple heliostats.

In yet another aspect, the reflector may be configured such that the first part has first wavelength distribution and the second part has a second wavelength distribution.

In still another aspect, the reflector may be configured such that the first part has first wavelength distribution and the second part has a second wavelength distribution. The first wavelength distribution may be a band between portions of the second wavelength distribution. In yet another aspect, the second wavelength distribution may include high and low pass ranges flanking the first wavelength distribution.

In another aspect, the surface may include a dichroic mirror. The reflector may be configured such that the first part has first wavelength distribution and the second part has a second wavelength distribution responsive to the reflectance/transmittance properties of the dichroic mirror.

In another aspect, the reflector may have alternating reflecting and photovoltaic conversion layers. The alternating layers may be configured to permit the partial transmission of light through at least one of the layers to another of the layers.

In another aspect, the reflector may be at least part of a heliostat whose surface is dished to concentrate light reflected therefrom. In another aspect, the reflector may be at least part of a parabolic trough. In yet another aspect, the reflector may be at least part of a cylindrical trough. In still another aspect, the reflector may be at least part of a parabolic or cylindrical trough. In another aspect, the reflector may be at least part of a linear Fresnel reflector.

In a further aspect, the solar power system may include a controller configured to selectively aim the reflector such that the reflector is normal to incident sunlight. The controller may selectively aim the reflector such that the reflector is normal to incident sunlight at times when the angle formed by the receiver, the reflector and the sun, with the reflector at the angle vertex, is greater than a predefined angle. In another aspect, the controller may selectively aim the reflector such that it is normal to incident sunlight at times when the production of the system peaks due to peak insolation levels and to reflect sunlight to the solar receiver at other times. In still another aspect, the controller may be configured to selectively aim the reflector such that it is normal to incident sunlight at times when the angle formed by the receiver, the reflector and the sun, with the reflector at the angle vertex, is greater than a predefined angle. The controller may be further configured to selectively aim the reflector such that it is normal to incident sunlight at times when the total amount of flux available to the system is above a certain level. In still another aspect, the controller may be configured to selectively aim the reflector such that it is normal to incident sunlight at times when the total amount of flux available to the receiver is above a certain level.

In another aspect, the reflector may be configured such that the first part has first wavelength distribution and the second part has a second wavelength distribution. The surface of the reflector may have a photovoltaic converter that converts light of the first wavelength distribution to electricity with a higher probability than wavelengths of the second wavelength distribution.

In another aspect, the reflector surface may include a reflecting surface and a photovoltaic layer on a transparent substrate overlying the reflecting surface. In another aspect, the reflector surface may include a reflecting surface and a photovoltaic dye layer on a transparent substrate overlying the reflecting surface. In still another aspect, the reflector surface may include a photovoltaic layer on a reflective substrate. In another aspect, the reflector surface may include a photovoltaic transparent thin film on a reflective substrate. In yet another aspect, the reflector surface may include a photovoltaic amorphous silicon thin film on a reflective substrate.

In a further aspect, the solar power system may include a controller configured to selectively aim the reflector such that it reflects sunlight onto the receiver or faces the reflector surface toward the sun responsively to at least one of parameters indicating instant electricity production of the system, revenue or profit generation of the system, instant energy conversion efficiency of the system, alternatively electricity production of the system, and revenue generation or profit generation of the system cumulated over a time period

In a further aspect, the solar power system may include additional reflectors configured to reflect all the sunlight received thereby. In a further aspect, the solar power system may include additional reflectors configured to reflect all the sunlight received thereby to the receiver.

In a further aspect, the solar power system may include non-photovoltaic heliostats. The reflector may be one of multiple photovoltaic heliostats. The non-photovoltaic heliostats may be positioned relative to the receiver so as to form less acute angles with the sun and the receiver during a greater fraction of a production period of the year than the photovoltaic heliostats. The positions of the photovoltaic heliostats and non-photovoltaic heliostats may be chosen such that the angle of incidence on the photovoltaic heliostats tends to be lower while reflecting sunlight to the receiver than the non-photovoltaic heliostats.

In a further aspect, the solar power system may include non-photovoltaic heliostats. The reflector may be one of multiple photovoltaic heliostats. Each photovoltaic heliostat may have an optical acceptance angle. The non-photovoltaic heliostats may be located in positions such that, when reflecting sunlight toward the receiver, they form angles with the sun and the receiver during a substantial fraction of a production period that is lower than the optical acceptance angle. The positions of the photovoltaic heliostats and non-photovoltaic heliostats may be chosen to provide a highest possible utilization factor of the photovoltaic conversion capability of the photovoltaic heliostats.

An embodiment of the present invention may include a mechanism for accepting energy from a source and redirecting the energy therefrom in response to certain conditions. The redirecting the energy may serve to compensate a central energy production system and to take maximum advantage of the energy that is available.

In an aspect, the source is the sun and the energy from the source is solar radiation. In another aspect, the mechanism for accepting and redirecting energy is a reflector. In yet another aspect, the mechanism is a panel that provides integrated reflection and energy conversion.

In another aspect, one or more energy redirectors may also have the ability to convert accepted energy directly into some other form of energy themselves. In an alternative aspect, the one or more energy redirectors may also have the ability to direct the energy selectively to alternative converters.

In still another aspect, the redirectors may split the energy into different bands and direct the energy toward a converter that can make the most efficient use of it. In an aspect, the energy may be split such that one waveband is directed to a photovoltaic converter and another waveband is directed to a thermal converter.

In yet another aspect, the redirector may be a mirror. In another aspect, the redirector may be a prism. In another aspect, the redirector may be any other suitable energy redirector.

In another aspect, a controller may be provided which functions to redirecting the energy under predefined circumstances.

In another aspect, the mechanism for accepting energy and redirecting the energy may serve to recapture otherwise wasted excess total system flux.

In another aspect, the mechanism for accepting energy and redirecting the energy may include a central mirror with variable reflectivity. The central mirror may rapidly modulate the total flux to guard against emergency conditions.

In yet another aspect, the mechanism for accepting energy and redirecting the energy may capture energy when there is low direct insolation but high total diffuse insolation. The energy may be captured by distributed photovoltaic converting heliostats.

In still another aspect, the mechanism for accepting energy and redirecting the energy may moderate the flux during an unsteady operating period of the receiver but capture the energy that would otherwise be lost. In an aspect, the unsteady operating period of the receiver may be a startup period of a boiler.

In still another aspect, the mechanism for accepting energy and redirecting the energy may make use of solar energy at wavelengths that are illsuited to conversion by economical photovoltaic devices. In an aspect, the solar energy at wavelengths ill-suited to conversion by economical photovoltaic devices may be directed to a different type of converter such as thermal receiver of a concentrating system.

Objects, advantages, and novel features of the present invention will become apparent from the following detailed description of the invention when considered in conjunction with the accompanying drawings.

### BRIEF DESCRIPTION OF THE DRAWINGS

FIGS. 1 and 2 are diagrammatic elevation views of a plurality of heliostats and a central power tower in accordance with different embodiments of the invention.

FIG. 3a is a diagrammatic elevation view of a heliostat and power tower illustrating the incidence and reflection angles of solar radiation with respect to focusing on the tower.

FIG. 3b is a diagrammatic elevation view similar to FIG. 3a, showing the same heliostat pointing toward the sun in another operating mode.

FIGS. 4 and 5 are diagrammatic cross-sections of heliostat mirrors configured for both reflection and photovoltaic conversion in accordance with preferred embodiments of the invention.

FIGS. 6a and 6b illustrate a heliostat with features relating to a photovoltaic conversion capability.

FIG. 6c illustrates a field of heliostats with subgroups with assigned members to generate electrical power for the subgroup.

FIG. 7 illustrates a variable reflector using mechanical shutters.

FIGS. 8 and 9 illustrate a trough or dish concentrating reflectors with photovoltaic conversion.

FIG. 10 illustrates various system arrangements.

FIG. 11 is a diagrammatic elevation view of a plurality of heliostats, an intermediate reflector with an energy converter, and a central receiver.

FIG. 12 is a diagrammatic elevation view of a plurality of heliostats, a pair of intermediate reflectors, and a pair of receivers.

### DETAILED DESCRIPTION OF THE INVENTION

A concentrating solar power (CSP) system uses solar radiation that is concentrated by reflecting or otherwise focusing incident insolation from a larger area, usually comprising mirrors but optionally including a lens, onto a smaller area. The smaller area preferably comprises a receiver where the radiation is converted to some useful form, such as heat which is optionally used for the production of electricity or by directly converting the sunlight to electricity such as by photovoltaic conversion. Most CSP systems include tracking or calculating the apparent position of the sun at various intervals in order to achieve a desired angle of reflection that can utilize the direct normal component of the solar radiation.

A CSP may include at least one solar power tower and at least one set of heliostats equipped with mirrors for reflecting solar radiation onto a receiver positioned on the tower. Alternatively, a CSP system may include a plurality of parabolic trough mirror assemblies which reflect solar radiation onto a receiver, such as a fluid-conveying pipe, situated above, axially aligned with, and in the focus of, the parabolic trough. In another alternative configuration, a CSP system may include a hyperbolic or parabolic dish comprising multiple mirror facets which reflect solar radiation onto a receiver at the focus. In yet another alternative configuration, a plurality of substantially flat mirrors are assembled to form a kind of ad hoc single-axis Fresnel lens that reflects sunlight onto receivers, such as fluid-conveying pipes or concentrated photovoltaic modules, which are positioned above, axially aligned with, and in the focus of, the ad hoc Fresnel lens.

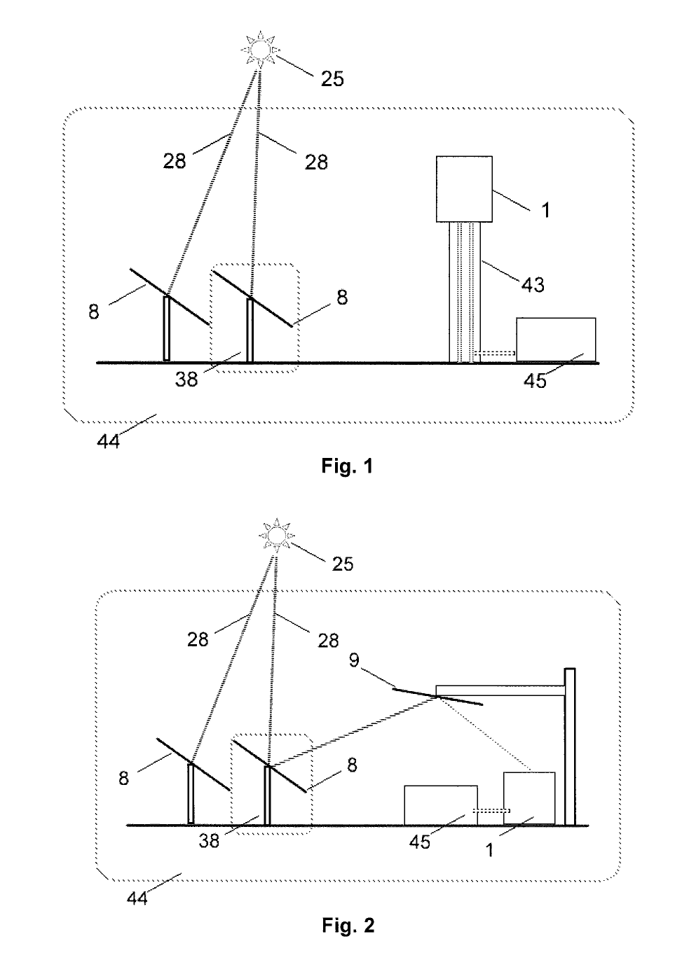

In some embodiments, the CSP system includes a solar power tower system wherein a central receiver is located at the top of a receiver tower or at some other location, for example if an intermediate reflector is used to bounce light received at the top of a tower down to a receiver located at ground level. Referring now to the figures and in particular to FIG. 1, a solar power system 44 is provided in which heliostats 38 include mirrors 8 that reflect incident solar radiation 28 onto a receiver 1 in which a working fluid (not shown) is heated for later use in an electric power generating plant 45, and/or in which electricity is generated by photovoltaic conversion of reflected light. The heliostat-mounted mirrors 8 are capable of tracking the apparent movement of the sun 25 across the sky each day in order to maintain the reflective focus in the direction of the receiver 1 as the angle of the incident radiation 28 changes. The receiver 1 is located atop a tower 43, or in an alternative embodiment, shown in FIG. 2, is located on the ground, and the heliostat-mounted mirrors 8 reflect solar radiation onto one or more suspended mirrors 9 which further reflect the radiation onto the receiver 1.

According to a preferred embodiment, at least some of the heliostats are capable of reflecting at least some of the incident solar radiation onto a receiver and also of converting at least some of the incident solar radiation directly into electricity through photovoltaic conversion. In this specification photovoltaic conversion has its usual meaning but may also be taken to include the generation of electricity from solar energy by electrochemical means in a dye-sensitized solar cell or similar arrangement. In some embodiments a heliostat can alternately perform one function (reflection) or the other (photovoltaic conversion) at different times, and in other embodiments a heliostat can perform both functions at the same time. This is accomplished with a heliostat that includes alternating reflecting and photovoltaic conversion layers, as described in the embodiments, which allow the partial transmission of light through at least one layer to another.

Non-concentrating photovoltaic systems are known in the art and can be configured in various ways, including flat-plate horizontal, flat-plate tilted, single-axis tracking, and double-axis tracking. Double-axis tracking is known to provide the highest energy conversion efficiency of any of these because the photovoltaic cells are made to track, with two axes of movement, the apparent movement of the sun across the sky so as to point directly toward the sun at all times. This exposes the photovoltaic cells to both diffuse solar radiation and direct normal insolation, that is, direct insolation while the photovoltaic collector is aligned in a plane normal to the vector of the incident radiation.

However, conversion of solar radiation to electrical energy by direct in-situ photovoltaic conversion to electrical energy, even with double-axis tracking, is generally less efficient than a solar power tower system that involves reflection of incident solar radiation onto a receiver capable of converting the reflected radiation into heat in a fluid which is then transported to an electricity generating means such as a turbine that can convert thermal energy in the heated fluid to electricity. Similarly, conversion of solar radiation to electrical energy by direct in-situ photovoltaic conversion to electrical energy is generally less efficient than a solar power tower system that includes concentrated photovoltaic modules, which involves reflection onto a receiver capable of converting the reflected and concentrated radiation directly into electricity by means of high-efficiency concentrated (i.e., multi-junction or multi-bandgap) photovoltaic cells.

Nonetheless, there are times when the instant efficiency of reflecting solar radiation from certain heliostats in a solar power tower system to a receiver can be less than the instant efficiency of converting that solar radiation to electrical energy by direct in-situ photovoltaic conversion. For example, a heliostat located to the east of a receiver in the northern hemisphere will reflect incident solar radiation on the receiver with relatively large cosine losses during the early morning hours. Cosine losses in a tower system occur because the effective reflection area of a heliostat is reduced by the cosine of one-half of the angle between incident radiation and reflected radiation. During those morning hours, the angle between incident radiation and reflected radiation is substantially more than 90 degrees and therefore cosine losses significantly impact on the energy conversion efficiency of energy impinging on such a heliostat. In a first mode of operation, such a heliostat equipped with photovoltaic conversion means in accordance with any embodiment of the present invention, could be directed by a control system or system operator to turn toward the apparent position of the sun in the sky instead of its normal tracking position of halfway between the sun and the receiver, and convert both diffuse and direct insolation to electricity with a higher energy conversion efficiency.

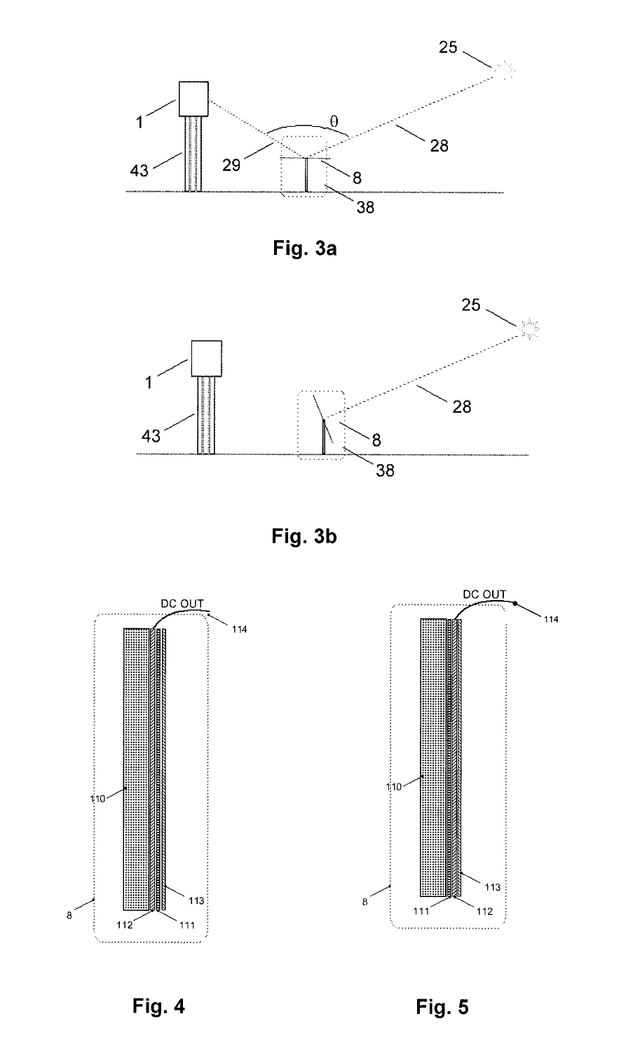

Referring again to the figures and in particular to FIGS. 3a and 3b, FIG. 3a illustrates the situation wherein the sun 25 is relatively low in the morning sky, and angle θ defines the angle between incident radiation 28 and reflected radiation 29, which is reflected, by mirror 8 mounted on heliostat 38, onto receiver 1 on tower 43. Angle θ is substantially larger than 90 degrees and the attendant cosine losses mean that the efficiency of solar-to-electric energy conversion with respect to this heliostat is accordingly lowered. FIG. 3b shows that the heliostat-mounted mirror 8 can be turned, alternatively, to face the sun 25 directly in order to receive direct normal insolation, as well as diffuse insolation, for direct, in-situ photovoltaic conversion if the heliostat-mounted mirror 8 is configured in accordance with one of the embodiments described herein.

There are also times in the normal operation of a solar power tower system when a heliostat is directed to turn away from the sun and not reflect light onto a receiver because the incremental energy reflected by the heliostat would cause the receiver to exceed its rated output. This occurs because solar power systems are not sized in accordance with the peak solar conditions of, for example, solar noon on a summer day, but rather in accordance with an economic optimization that involves a tradeoff between excess capacity during times of peak solar radiation and inadequate collected solar radiation at other times. The distribution of solar radiation over the hours of the year tends to have a normal distribution peaking in summer, and therefore a solar power system sized to provide a given rated energy output at less than peak solar radiation will always have excess heliostat capacity during some peak hours. Instead of simply turning these heliostats toward the ground, as is common practice in solar-thermal only or concentrated photovoltaic plants, such heliostats could be directed instead to turn directly toward the sun (rather than at a angle that would reflect incident radiation onto the receiver) and convert both diffuse and direct normal insolation to electricity through photovoltaic conversion.

In another mode of operation, a heliostat in accordance with the present invention can be directed to track the sun so as to reflect incident solar radiation onto a receiver. At the same time, the photovoltaic means installed on the heliostat can convert some of the incident solar radiation directly to electricity, including diffuse radiation and direct radiation, although the amount of direct radiation converted will be reduced in this mode in accordance with the cosine of half of the angle between the incident radiation and the reflected radiation (angle θ in FIG. 3a).

Another mode of operation may be provided under conditions where clouds scatter the light and prevent effective operation of a solar thermal concentrating system employing heliostats. Under such conditions, photovoltaic conversion heliostats can be positioned at an angle optimized for photovoltaic conversion, for example, of diffuse light. For example, the heliostats may be positioned to face the sun or positioned horizontally or any other position depending on which affords the highest electrical generating rate.

Another mode of operation may be provided to compensate for non-uniform illumination of the photovoltaic layer, or layers of multiple heliostats, which could cause electrical problems depending on how the portions of the layer are electrically interconnected or the heliostats are electrically interconnected. The mode may change heliostats with photovoltaic conversion to full reflection or otherwise electrically compensate during such times. Such non-uniform illumination could occur at certain times of the day or year when some heliostats cast shadows on others, for example.

In order for a heliostat reflector to be capable of both reflection and photovoltaic conversion, the incident light may be passed through a reflecting layer to reach a photovoltaic conversion layer or alternatively, to pass through a photovoltaic conversion layer to reach a reflecting layer to pass through the photovoltaic conversion layer again.

In an embodiment, a heliostat mirror includes at least a photovoltaic conversion layer and a partially reflecting layer, where the partially reflecting layer is positioned between the sun and the photovoltaic conversion layer. Referring to FIG. 4, a heliostat mirror 8 includes an optional front glass layer 110, a partially reflecting layer 112, a photovoltaic conversion layer 111 and a backing layer 113. The optional front glass layer 110 is preferably low-iron float glass with a thickness between 2 and 6 mm but can be made of any other acceptable material, such as a transparent polymer or ceramic material. The backing layer 113 is configured for protection of the photovoltaic conversion layer 111 and optionally for facilitating attachment to mounting or support elements for installation on a heliostat, and may contain metal or polymeric materials, or both in combination or in layers. The photovoltaic conversion layer 111 is optimally connected via a conductor 114 (for example, an ohmic conductor) to an external load such as a transformer or a motor.

In a preferred embodiment, the partially reflecting layer 112 is spectrally selective. For example, a dichroic filter may reflect light at certain wavelengths while transmitting light at other wavelengths. As is known in the art, by suitable selection of the thickness and number of layers, the wavelength range of the passband (or waveband) of such a filter can be determined. In a preferred embodiment, the passband, the portion of the spectrum that is transmitted by (or passed through) the spectrally-selective partially reflecting layer, is chosen to substantially coincide with or overlap the portion of the spectrum that is most effectively converted by the photovoltaic conversion layer 111, for example, the band associated with the bandgap of the semiconductor component of the photovoltaic conversion layer. By limiting the arrival of light that is outside the bandgap (mainly the portion of the spectrum where photon energy is less than the bandgap) the amount of heat buildup in the photovoltaic conversion layer can be reduced, while at the same time making the other wavelengths available for reflection when the mirror is deployed in a reflecting mode.

The partially reflecting layer 112 may be provided, in one or multiple applications, by thin film deposition on the photovoltaic conversion layer. In a particularly preferred embodiment, the photovoltaic conversion layer is provided by thin film deposition on the backing layer 113, and the partially reflecting layer is also formed on over photovoltaic conversion layer 111. The photovoltaic conversion layer 111 and reflecting layer 112 can be formed by vapor deposition, printing or any suitable process.

In another embodiment, a heliostat mirror includes at least a photovoltaic conversion layer and a reflecting layer, where the photovoltaic conversion layer is positioned between the sun and the reflecting layer. Referring to FIG. 5, a heliostat mirror 8 includes an optional front glass layer 110, a photovoltaic conversion layer 111 which partially transmits light, a reflecting layer 112 that is preferably a perfect reflector, and a backing layer 113. The photovoltaic conversion layer 112 is optimally connected via a conductor 114 to an external load such as a transformer. The photovoltaic conversion layer 111 is at least partially transparent and can be formed as a thin film on a separate substrate or formed on the reflecting layer 112. An example of a suitable material for a partially transparent photovoltaic conversion layer is Power Glass, developed by Xsunx, Inc., of Aliso Viejo, Calif. Alternatively, the photovoltaic conversion layer can employ dyes or ink applied by a suitable process on the reflecting layer. Any method of forming such a layer is suitable and may be formed on materials such as glass, metal or plastic, any of which could be used in a reflecting layer.

The photovoltaic conversion layer 111 may be configured to convert at least a portion of incident light to electricity before it reaches the reflecting layer 112 and to convert at least a portion of reflected light to electricity after it has been reflected by the reflecting layer 112. The portion of the incident light reflected and subsequently photovoltaically converted may be in the same portion of the spectrum that was photovoltaically converted before being reflected, or it may overlap that portion of the spectrum, or it may be in a different portion of the spectrum. For example, the reflecting layer can include a fluorescing filter that alters the wavelength of at least a portion of the light reaching the reflecting layer. In another example, a phosphor or wavelength converting layer may be provided adjacent to the photovoltaic layer to thereby convert incident solar radiation into wavelengths at which the photovoltaic layer is responsive. In yet another example, phosphor or wavelength converting particles can be incorporated within the photovoltaic or reflecting layer. In other embodiments, the reflecting layer 112 of FIG. 4 may include a liquid crystal layer configured to transmit or reflect light depending on its state.

In all of the embodiments, where possible, the discussions relating to heliostats FIG. 1, reference numeral 8, and central reflector embodiments FIG. 2, reference numeral 9, are interchangeable. That is, all of the features described with regard to a reflector/photovoltaic converter can be provided in the heliostat 8, the central or intermediate reflector 9, or both.

One mechanism for controlling the state of the reflector is by using a local algorithm implemented through a microcontroller. For example, if the ratio of the intensity of diffuse light (light coming from many directions) to the intensity of direct light (light from a single direction) exceeds a threshold, the reflector may switch from reflecting to photovoltaic mode. The local controller may also employ time of day information, total insolation, and other information to control its state.

Equipping a heliostat with a dual-function mirror in accordance with any of the preceding embodiments may cost more than a simple reflecting mirror as well as reduce the total reflectivity of any such mirror to some degree, and therefore it may be preferable to have a select subset of heliostats in a solar power tower system to be so equipped. Preferably the subset is chosen according to an optimization scheme that takes account of the acceptance angle limitations of the photovoltaic portion of the reflector. For example, some heliostats will provide more total photovoltaic conversion over a period of time because the incident light is within the range of acceptance angles of the photovoltaic converting layer for a greater fraction of that period of time whilst the heliostat is in a mode in which it is tracking the sun for concentrating it on a central receiver. For example, if the system is configured such that the main contribution of photovoltaically-converted energy is from heliostats to the east of a receiver in the early morning and from heliostats to the west of a receiver in the late afternoon, then it may be economically feasible to equip those heliostats with the dual-function mirrors but not others. In an alternative embodiment, it is possible to preselect the heliostats which would not be needed for reflection of solar radiation onto a receiver during peak summer hours because of excess capacity at peak, and then to equip those heliostats with the dual-function (both reflection and photovoltaic conversion) mirrors. In another alternative embodiment, all of the heliostats in a solar power tower system are so equipped.

Heliostats may be configured to allow rapid removal and replacement on their supports. In a variation of this concept, the heliostats are configured to allow the components associated with the photovoltaics to be removed and transported with the heliostat in a convenient manner with low risk of misconnection and damage. For example, a power management module, energy storage, controller, etc. could be combined in a single housing. In a preferred method, the heliostats are moved around during the course of the year as the solar declination angle changes to allow heliostats with photoconversion to be positioned where the sun angle is within the acceptance angle for a greater fraction of the day. For example, this could be done according to a regular schedule on the order of weeks or months apart depending on the rate of change of declination angle.

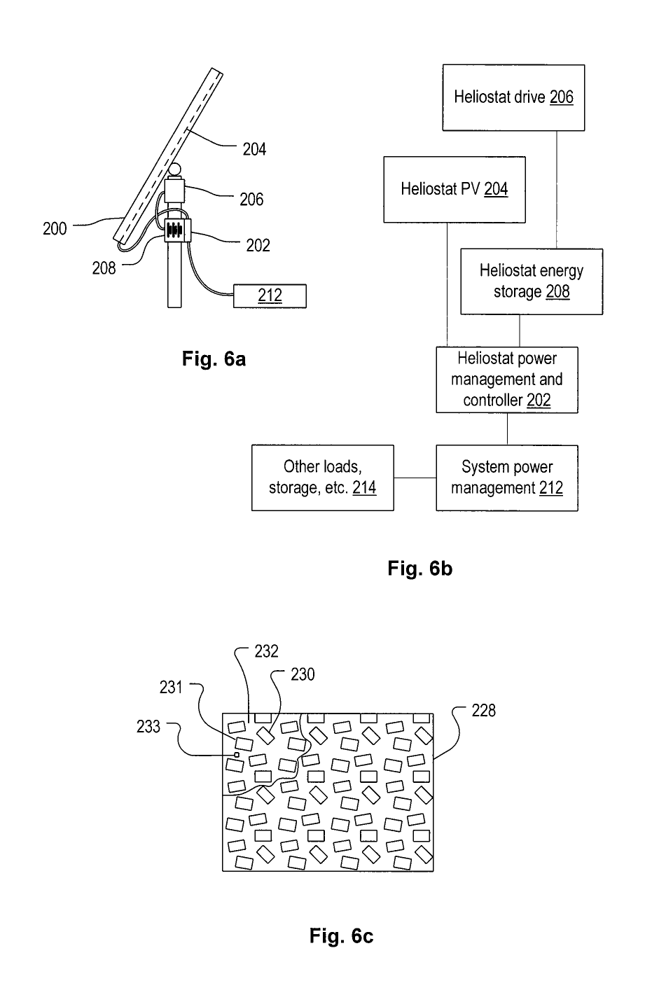

Referring to FIGS. 6a and 6b, in embodiments, electricity generated by a photovoltaic layer 204 in a heliostat reflector 200 in accordance with any of the embodiments herein is used for powering at least one positioning drive 206 of the heliostat reflector 200. Power may be supplied to a power management unit 202 which may have a controller configured to control the heliostat drive 206 autonomously or semi-autonomously. Energy may be stored locally, semi-locally (See FIG. 6c and attending discussion) or centrally. Energy storage 208 may be provided by a battery, ultracapacitor, flywheel, thermal storage means, or any other suitable device. In a further embodiment, the electricity is used for providing electricity to a system power management system 212 which may provide power to other loads such as a recirculation pump in a receiver boiler 214. In a variation, the electricity is transmitted to a transformer or rectifier and sold. Referring to FIG. 6c, power from a photovoltaic-generating heliostat 230 may be provided to other heliostats 231 in each subset 232 of a field 228. Each subset may have a respective energy store 233.

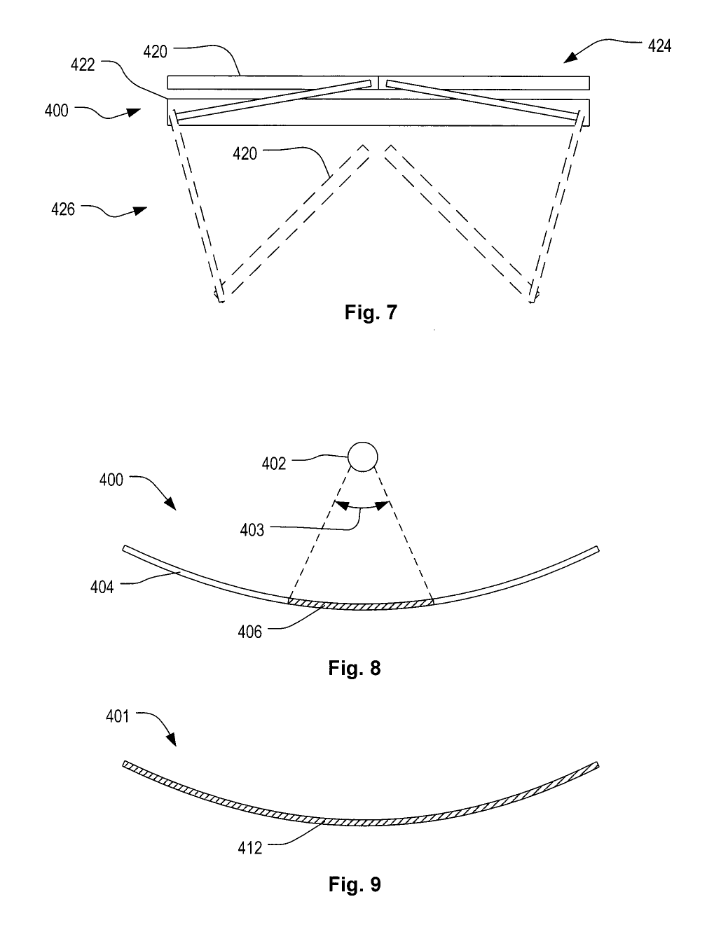

FIG. 7 illustrates a reflector device 400 with a back element 422 and an overlying elements 420 that can be selectively deployed; placed over the back element 422 as indicated at 424 (solid lines); or stored as indicated at 426 (broken lines). The overlying elements 420 may be opaque or transparent photovoltaic elements used in combination with the back element 422 having a reflective surface. The back element 422 may be a reflective (mirror) element, a photovoltaic element, or a reflective element with a photovoltaic layer element overlying it. The overlying elements 420 may be waveband filters, such as dichroic filters, with photovoltaic layer on the back element 422 in another embodiment. Alternatively, the overlying element may be transparent or opaque photovoltaic elements with the back element 422 being a reflector. The above configuration may be used in heliostats FIG. 1, reference numeral 8, central reflectors FIG. 2, reference numeral 9, or both.

In an alternative configuration, a variable reflecting layer may overlie the backing member. The variable reflecting layer may be provided between the photovoltaic conversion layer and the sun, so as to regulate the amount of light reaching the photovoltaic conversion layer versus the amount of light reflected. For example, at times when maximum reflection is desired, the variable reflecting layer can be adjusted so as to reflect most of the light incident thereon. Conversely, at times when maximum photovoltaic conversion is desired, the variable reflecting layer may be adjusted so as to transmit most of the light incident thereon to the photovoltaic conversion layer.

Such a variable reflecting layer could be embodied in an LCD window. In another variation, a variable reflecting layer may be provided by one or more antireflection (quarter wavelength) films overlying a transparent substrate, where the film has a selectable index of refraction. In still another variation, a variable reflecting layer may be achieved by a plurality of dielectric films of a specific thickness designed to reflect a specific waveband, wherein the reflectance waveband may be shifted using electrical means. Such a feature may be achieved by employing materials that have a thermo-optic or electro-optic effect. Thus, an electric field or current applied to the film may effect a change in the index of refraction sufficient to alter the reflectivity of the film at certain wavelengths. In yet another variation, an electrochromic reflecting layer could be employed for the variable reflector. As discussed, for example in U.S. Pat. No. 7,042,615 to Richardson, which is hereby incorporated by reference in its entirety, a variable reflectance layer can be realized by an electrochromic device, which transitions from a highly reflecting metallic state to a mainly transparent state by application of an appropriate electric field. Other examples of variable reflectors suitable for use in the present system can be found in U.S. Pat. No. 5,905,590 to Van Der Sluis et al. and U.S. Pat. No. 6,310,725 to Duine et al., both of which are hereby incorporated by reference in their entirety. The above configurations may be used in heliostats FIG. 1, reference numeral 8, central reflectors FIG. 2, reference numeral 9, or both.

FIG. 8 illustrates a trough or dish reflector 404 with a portion 406 having a photovoltaic portion. The portion 406 can have an overlying selective waveband filter or a variable reflective surface. Preferably, the angular size 403 of the portion 406 is chosen based on the acceptance angle of the photovoltaic portion such that when the reflector 404 is aimed at the sun, to focus light on the receiver 402, the sun's rays are within the acceptance angle of the photovoltaic portion 406. The reflector can be a Fresnel reflector, faceted, multi-element reflector with equivalent features and function in an alternative configuration. FIG. 9 shows a reflector trough or dish 401 in which the entirety of the reflector 412 contains a photovoltaic layer which may be accompanied by an overlying selective waveband filter or a variable reflective surface.

In other embodiments, a CSP system that is not a solar power tower system, as described above, includes mirror facets which are capable of reflecting at least some of the incident solar radiation onto a receiver and also of converting at least some of the incident solar radiation directly into electricity through photovoltaic conversion. The mirror facets include alternating reflecting and photovoltaic conversion layers, as described in the various embodiments above, which allow the partial transmission of light through at least one layer to another. The mirror facets can be configured in accordance with any of the embodiments described for heliostat mirrors, e.g., with a photovoltaic conversion layer between the reflecting layer and the sun, or vice versa, such as those illustrated in FIGS. 4 and 5.

In an example, a CSP system includes a plurality of parabolic trough assemblies superficially similar to the LS-3 collectors installed at the SEGS IX trough plant at Harper Lake, Calif., the design details of which are available on the website of the National Renewable Energy Laboratory. The LS-3 collector design employs 224 mirror panels in each collector assembly, and these mirror panels aggregately form an approximation of a one-curve solid parabola so that most of the solar radiation incident on the mirror panels reflects onto a heat collection pipe, acting as a receiver for reflected solar energy, which runs axially along the length of the assembly at the approximate focus of the parabola. According to the example, each of the mirror panels includes a reflecting mirror on the face of which has been printed an array of CIGS nanoparticles comprising a photovoltaic layer. The direct-current electrical output of the photovoltaic layers of the mirror panels in the assembly is used for powering the assembly's drive motor. In another example, only some of the mirror panels are equipped with a photovoltaic conversion layer. In yet another example, the direct current electrical output of the collector is used elsewhere in the CSP plant or sold to an electric utility after optionally being converted to alternating current electricity.

In another example, a CSP system includes a plurality of substantially flat mirrors assembled to form a kind of ad hoc single-axis Fresnel lens that reflects sunlight onto receivers which include concentrated photovoltaic modules, where the receivers are positioned above, and are axially aligned with and in the focus of, the ad hoc Fresnel lens. A suitable assembly is the Compact Linear Fresnel Reflector developed by Solar Heat and Power Pty Ltd. of Australia. According to the example, the receiver includes modules incorporating multi-junction or multi-bandgap photovoltaic cells, a suitable example of which is the EMCORE T1000 Triple-Junction High-Efficiency Solar Cell available from EMCORE Photovoltaics of Albuquerque, N. Mex. The flat mirrors are constructed in accordance with the embodiment illustrated in FIG. 4, wherein a photovoltaic conversion layer comprising a cadmium-telluride polycrystalline thin-film deposition is interposed between a backing layer and a spectrally selective mirror. The flat mirrors can be operated in various operating modes as described earlier with respect to heliostats in a solar power tower system, including a first operating mode of tracking the sun for reflection on the receiver, where radiation utilized for photovoltaic conversion is reduced by the cosine of the half the angle between the sun and the reflector; and a second operating mode of tracking the sun so as to face the sun, i.e., to utilize both diffuse and direct normal radiation. In the second operating mode, radiation impinging on the flat mirrors will be reduced by the cosine of the sun angle with respect to the horizontal disposition of the flat mirrors, but this cosine loss is nonetheless smaller than that which is typical of the first operating mode.

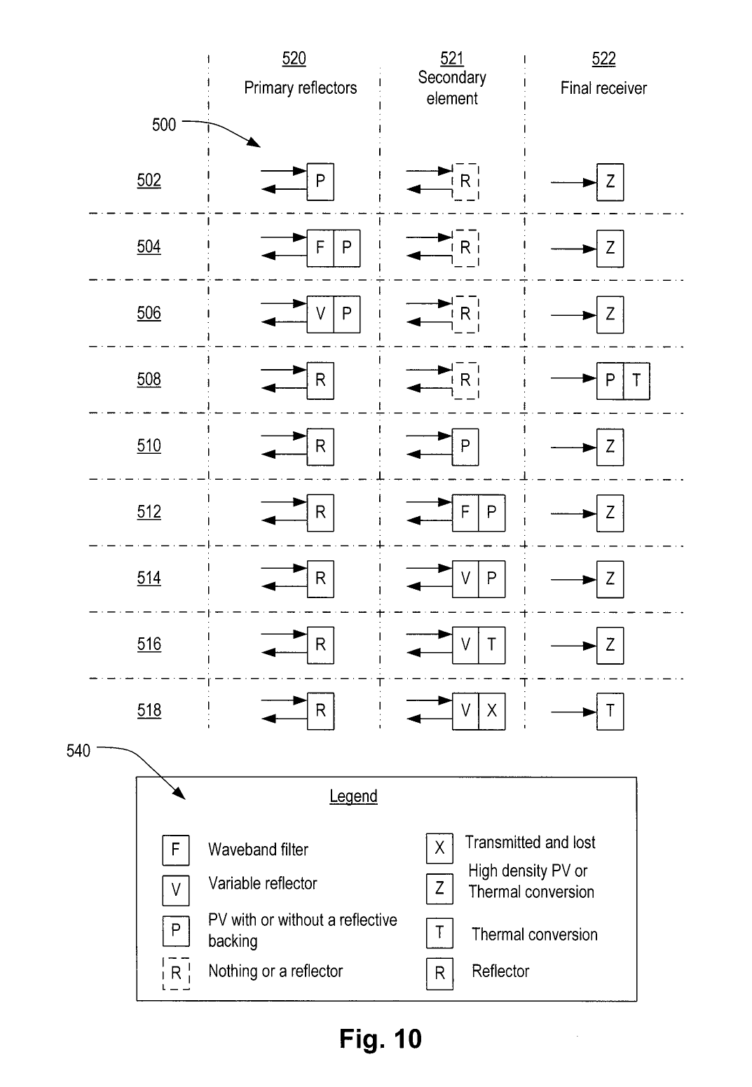

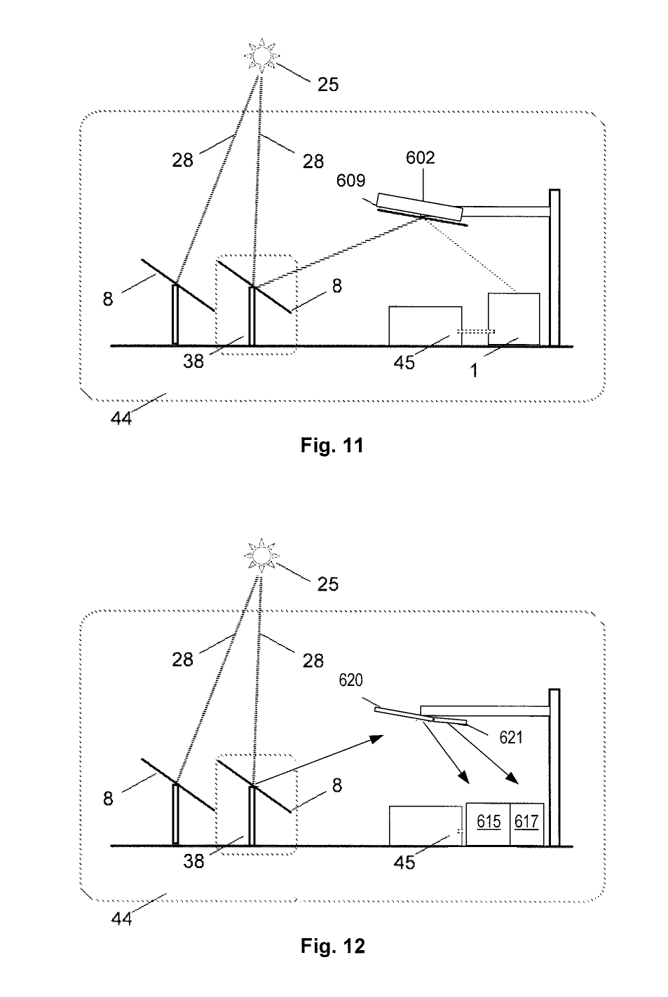

Referring to FIG. 10, there are various combinations of the features of the systems described above that will provide all or some of the benefits described and others. FIG. 10 shows some of these combinations in schematic form. Each of nine configurations is illustrated by a combination of icons (e.g., one such icon is indicated at 500). Each icon represents a component or component class, namely, a primary reflector or reflectors 520, for example, a field of heliostats, a secondary element 521 such as a reflector 9 in FIG. 2, and a final receiver 522. Each icon represents one or more possible combinations of subelements which are indicated in the legend 540. Specifically, “F” indicates a waveband filter which may overly a photovoltaic converter, for example. “V” indicates a variable reflector providing selectable degree of reflection and transmission. “P” indicates a photovoltaic converter as well as a photovoltaic converter with a reflective backing. In the latter variation, the photovoltaic converter would be at least partly transparent. Thus “P” represents two possible configurations. “R” represents a reflector. “R” in a dashed line box represents a reflector or no reflector as in a direct aiming system that does not employ an intermediate reflector (e.g., FIG. 1 or FIG. 2 configuration) “X” represents light passing through and being lost such as when a variable intermediate reflector is used to dump some of the energy to free space. “Z” represents a high density photovoltaic converter or thermal converter such as a boiler (See FIG. 11 and attending discussion below). “T” represents thermal conversion.

Configuration 502 has one or more primary reflectors with one or more of them having a photovoltaic conversion layer. The primary reflectors may be combined with a secondary reflector or the secondary reflector may be left out. A thermal receiver receives light reflected by the primary reflectors and the secondary element if present.

Configuration 504 has one or more primary reflectors with one or more of them having a photovoltaic conversion layer with an overlying filter, for example a waveband filter. The primary reflectors may be combined with a secondary reflector or the secondary reflector may be left out. A thermal receiver receives light reflected by the primary reflectors and the secondary element if present.

Configuration 506 has one or more primary reflectors with one or more of them having a photovoltaic conversion layer with an overlying variable reflector. The primary reflectors may be combined with a secondary reflector or the secondary reflector may be left out. A thermal receiver receives light reflected by the primary reflectors and the secondary element if present.

Configuration 508 has one or more primary reflectors. The primary reflectors may be combined with a secondary reflector or the secondary reflector may be left out. A thermal receiver with a receiving surface having an overlying photovoltaic conversion layer receives light reflected by the primary reflectors and the secondary element if present. The receiver converts thermal energy through the photovoltaic material overlying the receiver.

Configuration 510 has one or more primary reflectors. The primary reflectors may be combined with a secondary reflector having a photovoltaic conversion layer. A thermal receiver receives light reflected by the primary reflectors and the secondary element if present.

Configuration 512 has one or more primary reflectors. The primary reflectors may be combined with a secondary reflector having a photovoltaic conversion layer with an overlying filter, for example a waveband filter. A thermal receiver receives light reflected by the primary reflectors and the secondary element if present.

Configuration 514 has one or more primary reflectors. The primary reflectors may be combined with a secondary reflector having a photovoltaic conversion layer with an overlying variable reflector. A thermal receiver receives light reflected by the primary reflectors and the secondary element if present.

Configuration 516 has one or more primary reflectors. The primary reflectors may be combined with a secondary reflector having a thermal conversion element with an overlying variable reflector. The thermal conversion may be used to make the secondary element into an additional receiver to pick up and convert excess flux to thermal energy. For example, when the system is experiencing a peak insolation period, instead of dumping light by diverting heliostats, the variable reflector can be adjusted to allow more light to pass through to the thermal conversion element, which may be, for example, a boiler. A thermal receiver receives light reflected by the primary reflectors and the secondary element if present. Excess flux conditions may occur at peak operating periods or during startup when the system could have a predefined limit in the rate of increase of heat gain by a thermal receiver.

Configuration 518 has a variable intermediate reflector in which energy that is not reflected is transmitted and lost to the sky or an absorber to dissipate it. This would be used for purposes of dumping excess energy.

FIG. 11 illustrates a system with an intermediate reflector 609 with an energy converter 602 provided behind the intermediate reflector 609. This configuration is an example according to the configurations 510, 512, 514, 516, and 518 illustrated above. Energy converter 602 may be a thermal or photovoltaic converter or any other device that can convert solar energy to a usable form. 602 may, for example, be a boiler and the reflector 609 may be a variable reflector. Instead of diverting heliostats 8 when excess flux has to be dumped, the variable reflector may permit more light to impinge upon such boiler 602 and the thermal energy used for some useful purpose, such as preheating. Where 602 is a photovoltaic or other energy converter, under the same conditions, the “dumped” flux can be converted to usable form by adjusting the reflectivity/transmissivity characteristics of the reflector 609. In a further variation, reflector 609 is a variable reflector with nothing behind it to absorb the incident light such that the “dumped” flux is lost to the sky. Note that the above functions can be implemented by a beam splitter with a variable reflectance such that the energy converter 602 can be located on the ground.

Referring to FIG. 12, in another embodiment, two intermediate reflectors 620 and 621 are provided and can be configured in real time to divide the flux between two receivers 615 and 617. In an application, excess flux is directed by one of the reflectors 621 to receiver 617. In this example, 615 could be a thermal receiver for a solar thermal power plant with a rated capacity. When excess flux is received, the excess flux can be diverted by tiling the reflector 621 such that part of the energy falls on the receiver 617 instead of 615.

Certain features of this invention may sometimes be used to advantage without a corresponding use of the other features. While a specific embodiment of the invention has been shown and described in detail to illustrate the application of the principles of the invention, it will be understood that the invention may be embodied otherwise without departing from such principles.

1. An apparatus for use in a solar concentrating system, comprising:
a receiving member having layers configured respectively for reflecting and converting solar energy received thereby, the layers being in a mutually overlying arrangement and configured such that a first part of the solar received thereby is converted to energy of another form and a second part is reflected to a solar energy receiver; and
at least one energy power output configured to convey converted solar energy from the receiving member.

2. The apparatus of claim 1, further comprising a drive system configured to aim the member, the drive system being configured to receive energy from the energy output.

3. The apparatus of claim 1, wherein the layers include a photovoltaic conversion layer and the energy of another form is electrical energy.

4. The apparatus of claim 1, further comprising a drive system configured to aim the receiving member such that solar energy is received normal to the layers at a first time and to selectively aim the receiving member such that the second part is reflected to a solar energy receiver at a second time.

5. The apparatus of claim 1, wherein the layers include a photovoltaic converting layer and a reflecting layer.

6. The apparatus of claim 1, wherein the layers include a waveband filter layer, a photovoltaic converting layer, and a reflecting layer.

7. The apparatus of claim 1, wherein the layers include a photovoltaic converting layer and a reflecting layer with variable reflectivity.

8. The apparatus of claim 1, wherein the layers include a photovoltaic layer and at least one of a reflecting layer and a dichroic filter layer.

9. The apparatus of claim 1, wherein the layers include a filter layer and a photovoltaic layer having a range of wavelengths over which the photovoltaic layer exhibits peak conversion efficiency, the filter layer being configured to reflect light of wavelengths outside said range of wavelengths and to transmit light of wavelengths within said range of wavelengths.

10. A method for controlling at least one heliostat in a solar power system, the at least one heliostat having a reflecting layer and a conversion layer arranged such that such that a given light ray passes through both layers, the reflecting layer reflecting a portion of incident solar radiation, the conversion layer generating electrical power from another portion of the incident solar radiation, the method comprising:
at a first time, aiming the at least one heliostat so as to reflect incident solar radiation onto to a solar receiver; and
at a second time, aiming the at least one heliostat toward a different direction responsively to at least one of an excess flux condition, a low direct insolation condition, a non-steady state operating condition of a boiler, and a condition of non-uniform illumination of the conversion layer.

11. The method of claim 10, wherein the second time includes a time when insolation levels are below a predetermined threshold for use by the solar receiver.

12. The method of claim 10, wherein the second time includes a time when the at least one heliostat contributes more to electricity production by aiming the at least one heliostat directly at the sun than by reflecting incident solar radiation to the solar receiver.

13. A solar power system, comprising:
at least one reflector having a surface configured to convert a first part of the sunlight incident on the surface to electrical power and to reflect a second part of the sunlight incident on the same surface;
the at least one reflector being configured to direct the second part of the sunlight incident thereon to a solar receiver;
a power management system configured to receive electrical power derived from the first part from the reflector.

14. The system of claim 13, wherein the solar receiver includes a photovoltaic converter.

15. The system of claim 13, further comprising multiple heliostats, wherein the reflector receives sunlight from the multiple heliostats.

16. The system of claim 13, wherein the reflector is configured such that the first part has a first wavelength distribution and the second part has a second wavelength distribution.

17. The system of claim 13, wherein the reflector has alternating reflecting and photovoltaic conversion layers that are configured to permit the partial transmission of light through at least one of the layers to another of the layers.

18. The system of claim 13, further comprising a controller configured to selectively aim the reflector such that it is normal to incident sunlight at times when an angle formed by the receiver, the reflector and the sun, with the reflector at the angle vertex, is greater than a predefined angle.

19. The system of claim 13, further comprising a controller configured to selectively aim the reflector such that it is normal to incident sunlight at times at times when the power production of the system peaks due to peak insolation levels and to reflect sunlight to the solar receiver at other times.

20. The system of claim 13, further comprising a controller configured to selectively aim the reflector such that it is normal to incident sunlight at times when the total amount of flux available to the receiver is above a certain level.

21. The system of claim 13, wherein the reflector surface includes a reflecting surface and a photovoltaic layer on a transparent substrate overlying the reflecting surface.

22. The system of claim 13, further including a controller configured to selectively aim the reflector such that it reflects sunlight onto the receiver or faces the reflector surface toward the sun responsively to at least one of parameters indicating instant electricity production of the system, revenue or profit generation of the system, instant energy conversion efficiency of the system, alternatively electricity production of the system, and revenue generation or profit generation of the system cumulated over a time period

23. The system of claim 13, further comprising non-photovoltaic heliostats, the reflector being one of multiple photovoltaic heliostats, the non-photovoltaic heliostats being positioned relative to the receiver so as to form less acute angles with the sun and the receiver during a greater fraction of a production period of the year than the photovoltaic heliostats, whereby the positions of the photovoltaic heliostats and non-photovoltaic heliostats are chosen such that the angle of incidence on the photovoltaic heliostats tends to be lower while reflecting sunlight to the receiver than the non-photovoltaic heliostats.

24. The system of claim 13, further comprising non-photovoltaic heliostats, the reflector being one of multiple photovoltaic heliostats, each having an optical acceptance angle, the non-photovoltaic heliostats being located in positions such that, when reflecting sunlight toward the receiver, they form angles with the sun and the receiver during a substantial fraction of a production period that is lower than the optical acceptance angle, whereby the positions of the photovoltaic heliostats and non-photovoltaic heliostats are chosen to provide a highest possible utilization factor of the photovoltaic conversion capability of the photovoltaic heliostats.
